(19) United States
(12) Patent Application Publication
(10) Pub. No.: US 2025/0014959 A1
(43) Pub. Date: Jan. 9, 2025

(54) MICROELECTRONIC DEVICES INCLUDING RECESSES IN AN ENCAPSULANT MATERIAL AND ASSOCIATED SYSTEMS AND METHODS

(71) Applicant: Micron Technology, Inc., Boise, ID (US)

(72) Inventors: Manish Nayini, Telangana (IN); Koustav Sinha, Boise, ID (US); Christopher Glancey, Boise, ID (US); Quang Nguyen, Boise, ID (US)

(21) Appl. No.: 18/737,817

(22) Filed: Jun. 7, 2024

Related U.S. Application Data
(60) Provisional application No. 63/512,425, filed on Jul. 7, 2023.

(51) Int. Cl. H01L 23/31; H01L 21/56; H01L 23/00; H01L 23/498; H01L 25/10

(52) U.S. Cl. CPC H01L 23/3128; H01L 21/565; H01L 23/49816; H01L 23/562; H01L 24/16; H01L 24/32; H01L 25/105; H01L 2224/16225; H01L 2224/32225; H01L 2225/1058; H01L 2225/1094; H01L 2924/1815; H01L 2924/3511

(57) ABSTRACT

A microelectronic device includes a semiconductor die operatively coupled to a base structure. The device further includes an encapsulant substantially surrounding the semiconductor die. The device also includes one or more recesses vertically extending from an upper surface of the encapsulant to one or more locations at or proximate to an upper surface of the base structure.

### CROSS-REFERENCE TO RELATED APPLICATION

This application claims the benefit under 35 U.S.C. § 119 (c) of U.S. Provisional Patent Application Ser. No. 63/512,425, filed Jul. 7, 2023, the disclosure of which is hereby incorporated herein in its entirety by this reference.

### TECHNICAL FIELD

Embodiments of the present disclosure generally relate to microelectronic devices. In particular, embodiments of the present disclosure relate to microelectronic devices including recesses in an encapsulant material and associated systems and methods.

### BACKGROUND

During fabrication and testing, packaged microelectronic devices, for example, packaged semiconductor devices and assemblies, are subjected to a variety of stresses resulting at least from heating and cooling the semiconductor devices and assemblies during assembly of the devices on a substrate and encapsulation of the assembly, including application of an encapsulant (e.g., epoxy molding compound (EMC)), curing of the EMC, and/or reflow of external conductive elements (e.g., solder balls or bumps). These stresses may result in damage to the microelectronic device, such as delaminations or warpage of the semiconductor device.

As a consequence of many factors, including demand for increased portability, computing power, memory capacity and energy efficiency, microelectronic devices such as semiconductor devices and packages comprising such devices, are continuously being reduced in size. The sizes of the constituent features (i.e., critical dimensions) that form the devices, e.g., circuit elements and interconnect lines, as well as the pitch between (i.e., spacing) structures are also constantly being decreased to facilitate this size reduction.

The size reduction of the microelectronic devices and semiconductor devices and packages may result in an increased susceptibility to damage caused by the stresses resulting from heating and cooling the semiconductor devices and assemblies as the thickness of the devices are reduced. Furthermore, devices may be stacked to increase the circuit density of the devices and reduce the surface area. However, packages comprising stacked semiconductor devices may result in enhanced sensitivity to warpage of the package.

### BRIEF DESCRIPTION OF THE DRAWINGS

FIG. 1 illustrates a simplified, longitudinal cross-sectional view of a microelectronic device, in accordance with embodiments of the disclosure;

FIGS. 2A-4C illustrate simplified, longitudinal cross-sectional views of semiconductor device packages, in accordance with embodiments of the disclosure;

FIGS. 5 and 6 illustrate simplified, perspective views of semiconductor device packages, in accordance with embodiments of the disclosure; and

FIG. 7 is a schematic block diagram of an electronic system, in accordance with one or more embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbO₋ₓ₋), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbO₋ₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

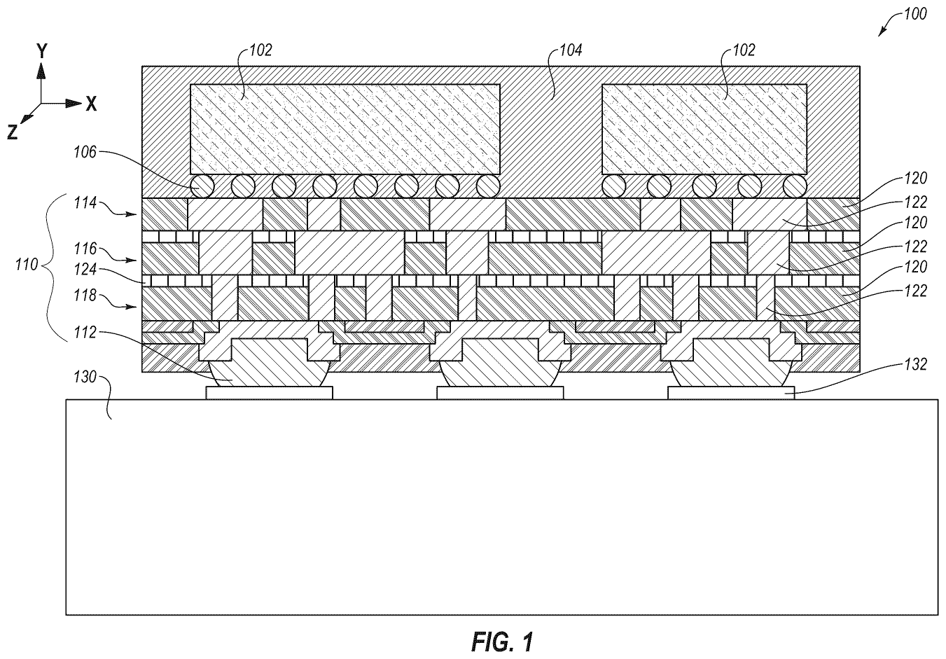

FIG. 1 illustrates a simplified, longitudinal cross-sectional view of a microelectronic device package in the form of semiconductor device package 100. The semiconductor device package 100 may include one or more semiconductor dice 102 disposed within an encapsulant, such as a mold material 104, for example, an EMC. As shown, the semiconductor dice 102 may be inverted in a “flip chip” orientation mechanically and electrically connected to a substrate in the form of an interposer layer 110 through one or more conductive elements 106 (e.g., solder bumps, solder balls, micro-bumps, etc.). In some microelectronic device packages, the semiconductor dice may be secured to an interposer by their back aides, and electrically connected to the interposer with wire bonds extending from the active surface to conductive pads of the interposer. The interposer layer 110 may be mechanically and electrically coupled to a package substrate 130 (e.g., base structure) through one or more other conductive elements in the form of solder bumps 112 connected to conductive contact pads 132 of package substrate 130. The conductive contact pads 132 may provide an electrical connection between the interposer layer 110 and the package substrate 130 through the one or more solder bumps 112. The package substrate 130 may comprise an organic material (e.g., printed circuit board) or an inorganic material (e.g., silicon or ceramic). Alternatively, for example, in wafer-level or panel-level packages, a redistribution layer (RDL) comprising one or more levels of conductive traces carried by dielectric material may serve as a substrate.

The interposer layer 110 may include one or more alternating conductive and insulating (i.e., dielectric) layers. For example, the interposer layer 110 may include a first patterned conductive layer 114 comprising a conductive material extending through a dielectric material disposed over a second patterned conductive layer 116 comprising a conductive material extending through a dielectric material disposed over a third patterned conductive layer 118 comprising a conductive material extending through a dielectric material. Each patterned conductive layer 114, 116, and 118 may include conductive portions 120 separated by insulating portions 122. The patterned conductive layers 114, 116, and 118 may further include a dielectric layer 124, such as an interlayer dielectric layer or an inter-metal dielectric layer formed on and/or in the conductive portions 120 of the respective patterned conductive layer 114, 116, and 118.

As the microelectronic device package is built, the semiconductor device package 100 may go through multiple heat cycles, such as reflow processes, mold curing processes, under bump metallization (UBM), baking, etc. When the semiconductor device package 100 is heated, moisture within the semiconductor device package 100, such as between the semiconductor dice 102 and the interposer layer 110, may evaporate. If the evaporated moisture is trapped within the semiconductor device package 100, the expansion of the moisture as it evaporates may create high vapor pressures in the area, which may cause the elements of the semiconductor device package 100 in the area to separate through de-laminations or bubbles (e.g., popcorning). Such separation may result in a failure in the semiconductor device package 100 or an associated microelectronic device package. Embodiments of the disclosure describe features that may be configured to provide an escape path for the evaporated moisture, which may substantially reduce or prevent damage to the semiconductor device packages 100 resulting from localized vapor pressure.

Warpage may also occur within the semiconductor device package 100 for a variety of reasons and at different times during the process of fabricating the semiconductor device package 100. For example, warpage may occur during one or more of the heating processes, such as the reflow processes, the mold curing processes, under bump metallization (UBM) processes, baking, etc. Generally, warpage of the semiconductor device package 100 is a result of a differing coefficient of thermal expansion (CTE) between the materials used to form the different portions of the semiconductor device package 100. As the semiconductor device package 100 experiences significant temperature changes throughout the forming process the differing CTEs may cause the semiconductor device package 100 to warp or bend as some portions of the semiconductor device package 100 expand or contract at greater rates than other portions of the semiconductor device package 100 responsive to temperature changes.

In some embodiments, the mold material 104 has a CTE that is significantly different from the CTE of other components (e.g., the semiconductor dice 102, interposer layers 110, and package substrate 130). Thus, an increase in the volume of the mold material 104 may increase warpage of the semiconductor device package 100 and reducing the volume of the mold material 104 may reduce the warpage of the semiconductor device package 100. Embodiments of the disclosure describe features that may reduce a volume of the mold material 104 substantially reducing the volume of the mold material.

As described in further detail below, semiconductor device packages of the disclosure include one or more recesses formed in the mold material. The recesses may be configured to provide an escape path for the evaporated moisture of the associated semiconductor device packages. Furthermore, the one or more recesses may result in a reduction in the volume of the mold material, such that the recesses may reduce the warpage caused by any CTE mismatch between the mold material and the other components of the associated semiconductor device package.

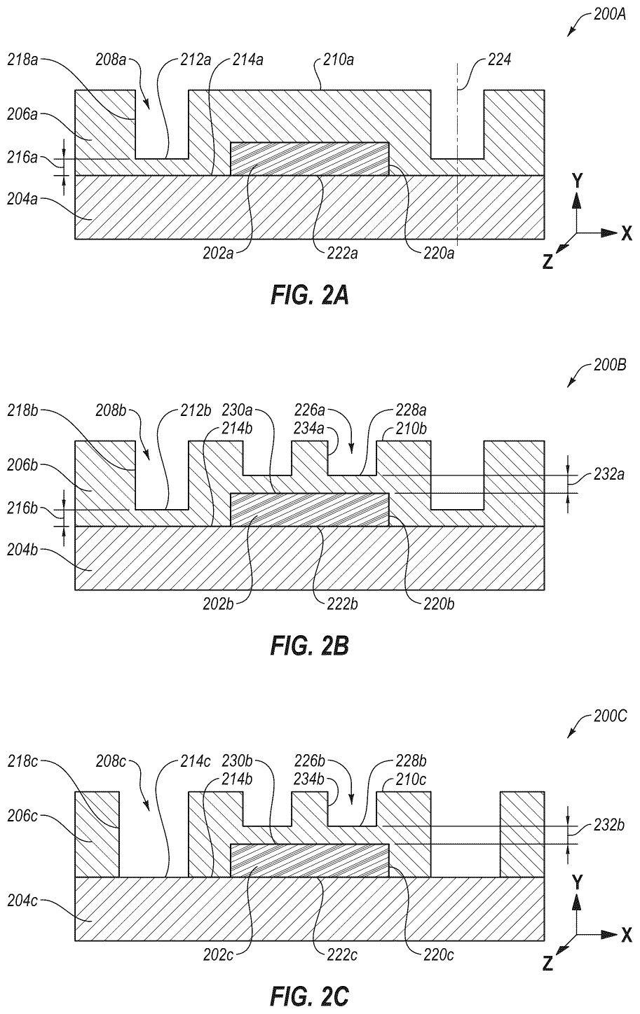

FIGS. 2A through 4C illustrate simplified, longitudinal cross-sectional views of different semiconductor device packages, in accordance with embodiments of the disclosure. FIG. 2A illustrates a semiconductor device package 200A. The semiconductor device package 200A includes a semiconductor die 202a secured to a substrate 204a. The substrate 204a may be base structure, such as a package substrate (e.g., the package substrate 130 described above with reference to FIG. 1), a redistribution layer (RDL) including one or more levels of conductive traces carried by dielectric material, or an interposer structure, such as the interposer layer 110 described above. The substrate 204a may include an organic material (e.g., a carbon-containing material) or an inorganic material (e.g., silicon or ceramic) as well as one or more conductive structures, such as one or more of conductive pads, conductive traces, pins, and sockets. The semiconductor die 202a is electrically coupled to one or more of the conductive structures. For example, the semiconductor die 202a may be directly coupled to the conductive structures through solder bumps, wirebonds, or other complementary conductive structures (e.g., pins, sockets). The substrate 204a may also include conductive structures that extend beyond a footprint of the semiconductor die 202a, such as one or more of traces and contact pads for wirebonding.

An encapsulant 206a may substantially surround the semiconductor die 202a. The encapsulant 206a may extend over a portion of an upper surface 214a of the substrate 204a and fully cover the semiconductor die 202a. The encapsulant 206a may include multiple recesses 208a extending into the encapsulant 206a from an outer surface 210a of the encapsulant 206a. In the embodiment illustrated in FIG. 2A the recesses 208a extend into the encapsulant 206a in an area outside of the footprint of the semiconductor die 202a. The recesses 208a are positioned adjacent to lateral surfaces 220a of the semiconductor die 202a. The encapsulant 206a may include multiple recesses 208a positioned around a perimeter of the semiconductor die 202a. The recesses 208a may be configured to define an escape path where vapors may exit the semiconductor device package 200A during one or more of the heating processes. Positioning the recesses 208a proximate the lateral surfaces 220a of the semiconductor die 202a reduces a volume of the mold material of the encapsulant 206a between the recesses 208a and an interface 222a between the semiconductor die 202a and the substrate 204a. Thus, moisture trapped in the interface 222a may evaporate and escape through the recesses 208a without creating excessive vapor pressures and potentially damaging the semiconductor die 202a or substrate 204a at the interface 222a.

In the embodiment illustrated in FIG. 2A, the recesses 208a terminate before reaching the upper surface 214a of the substrate 204a. Thus, a bottom boundary 212a of the recesses 208a is positioned a distance 216a from the upper surface 214a of the substrate 204a. The area between the bottom boundary 212a of the recess 208a and the upper surface 214a of the substrate 204a may be filled with the mold material of the encapsulant 206a. Thus, the mold material of the encapsulant 206a may remain to perform the insulating or other protective functions for any conductive structures of the substrate 204a positioned proximate the recesses 208a.

The recesses 208a may be defined by substantially vertical sidewalls 218a of the encapsulant 206a. The sidewalls 218a may be orientated parallel to one another, such that the recesses 208a individually exhibit a substantially rectangular cross-sectional shape in a Y plane where an upper boundary of the recesses 208a is defined by the outer surface 210a of the encapsulant 206a. A cross-sectional shape of the recesses 208a about an axis 224 of the recesses 208a in an X plane may be any shape, such as circular shapes, oval shapes, rectangular shapes, triangular shapes, among others. The shape of the recesses 208a may be selected based on structural features of the substrate 204a and the semiconductor die 202a. For example, the shapes of the recesses 208a may be selected such that the bottom boundaries 212a of the recesses 208a are not positioned over or proximate (e.g., such that the recesses 208a avoid) select features of the substrate 204a and semiconductor die 202a, such as contact pads or wirebonds. The shapes or positions of the recesses 208a may further be selected based on warpage concerns. For example, the recesses 208a may be positioned or shaped to pass over regions of the substrate 204a that are most susceptible to warpage. Positioning the recesses 208a over regions susceptible to warpage may reduce the warpage induced in the regions due to CTE mismatches between the mold material of the encapsulant 206a and the substrate 204a by reducing the volume of the mold material of the encapsulant 206a in the regions most susceptible to warpage.

The recesses 208a may be formed through one or more desirable processes. For example, the recesses 208a may be formed after the encapsulant 206a is formed through a material removal process, such as machining, dry-etching, or wet-etching processes. In another example, the encapsulant 206a may be formed with the recesses 208a, such as in a molding process with complementary protrusions extending from the mold or in an additive manufacturing process.

FIG. 2B illustrates a semiconductor device package 200B. The semiconductor device package 200B includes a semiconductor die 202b secured to a substrate 204b. In some cases, the semiconductor device package 200B may be a different portion of the semiconductor device package 200A illustrated in FIG. 2A. For example, a single semiconductor device package 200A or 200B may include regions with a configuration as illustrated in FIG. 2A and other regions with a configuration as illustrated in FIG. 2B. As described above, the substrate 204b may be a package substrate, a redistribution layer (RDL), or an interposer structure. The semiconductor die 202b is electrically coupled to one or more of the conductive structures, such as through solder bumps, wirebonds, and/or other complementary conductive structures (e.g., pins or sockets). The substrate 204b may also include conductive structures that extend beyond a footprint of the semiconductor die 202b, such as traces and/or contact pads for wirebonding.

An encapsulant 206b substantially surrounds the semiconductor die 202b. In some embodiments, the encapsulant 206b extends over a portion of an upper surface 214b of the substrate 204b and fully covers the semiconductor die 202b. In other embodiments, the encapsulant 206b extends over a portion of the upper surface 214b of the substrate 204b and is flush with an upper surface of the semiconductor die 202b, such that an upper surface of the semiconductor die 202b is exposed through the encapsulant 206b. The encapsulant 206b includes primary recesses 208b and secondary recesses 226a extending into the encapsulant 206b from an outer surface 210b of the encapsulant 206b. In the embodiment illustrated in FIG. 2B the primary recesses 208b extend into the encapsulant 206b in an area outside of the footprint of the semiconductor die 202b. The primary recesses 208b are positioned adjacent to lateral surfaces 220b of the semiconductor die 202b. The encapsulant 206b may include multiple primary recesses 208b positioned around a perimeter of the semiconductor die 202b. The primary recesses 208b may be configured to define an escape path where vapors may exit the semiconductor device package 200B during one or more of the heating processes. Positioning the primary recesses 208b proximate the lateral surfaces 220b of the semiconductor die 202b reduces a volume of the mold material of the encapsulant 206b between the primary recesses 208b and an interface 222b between the semiconductor die 202b and the substrate 204b. Thus, moisture trapped in the interface 222b may evaporate and escape through the primary recesses 208b without creating excessive vapor pressures and potentially damaging the semiconductor die 202b or substrate 204b at the interface 222b.

In the embodiment illustrated in FIG. 2B, the secondary recesses 226a extend into portions of the encapsulant 206b vertically overlying and within a horizontal area of the semiconductor die 202b. The encapsulant 206b may include multiple secondary recesses 226a therein positioned over the semiconductor die 202b. The secondary recesses 226a may be configured to define an escape path where vapors may exit the semiconductor device package 200B during one or more of the heating processes.

In the embodiment illustrated in FIG. 2B, the primary recesses 208b terminate before reaching the upper surface 214b of the substrate 204b and the secondary recesses 226a terminate before reaching an upper surface 230a of the semiconductor die 202b. Thus, a bottom boundary 212b of the primary recesses 208b is positioned a first distance 216b from the upper surface 214b of the substrate 204b and a bottom boundary 228a of the secondary recesses 226a is positioned a second distance 232a from the upper surface 230a of the semiconductor die 202b. The area between the bottom boundaries 212a, 212b of the primary recesses 208b and the secondary recesses 226a and the respective upper surfaces 214b, 230a of the substrate 204b and the semiconductor die 202b may be filled with the mold material of the encapsulant 206b. Thus, the mold material of the encapsulant 206b may remain to perform the insulating or other protective functions for any structures of the substrate 204b and the semiconductor die 202b positioned proximate the primary recesses 208b and the secondary recesses 226a.

The recesses 208b may be defined by substantially vertical sidewalls 218b of the encapsulant 206b. The sidewalls 218b may be orientated parallel to one another, such that the recesses 208b individually exhibit a substantially rectangular cross-sectional shape in a Y plane where an upper boundary of the recesses 208b is defined by the outer surface 210b of the encapsulant 206b. A cross-sectional shape of the recesses 208b about axes of the recesses 208b in an X plane may be any shape, such as circular shapes, oval shapes, rectangular shapes, triangular shapes, among others. As described above, the shapes of the recesses 208b, 226a may be selected based on structural features of the substrate 204b and the semiconductor die 202b. The shapes or positions of the recesses 208b, 226a may further be selected based on warpage concerns, such as to reduce a volume of the mold material of the encapsulant 206b in regions most susceptible to warpage.

FIG. 2C illustrates a semiconductor device package 200C. The semiconductor device package 200C includes a semiconductor die 202c secured to a substrate 204c. In some cases, the semiconductor device package 200C may be a different portion of the semiconductor device package 200A and/or 200B illustrated in FIGS. 2A and 2B. For example, a single semiconductor device package 200A, 200B, or 200C may include regions with a configuration as illustrated in FIG. 2A and/or 200B and other regions with a configuration as illustrated in FIG. 2C. As described above, the substrate 204c may be a package substrate, a redistribution layer (RDL), or an interposer structure. The semiconductor die 202c is electrically coupled to one or more of the conductive structures, such as through solder bumps, wirebonds, and/or other complementary conductive structures (e.g., pins or sockets). The substrate 204c may also include conductive structures that extend beyond a footprint of the semiconductor die 202c, such as traces and/or contact pads for wirebonding.

An encapsulant 206c substantially surrounds the semiconductor die 202c. The encapsulant 206c extends over a portion of an upper surface 214c of the substrate 204c and fully covers the semiconductor die 202c. The encapsulant 206c includes primary recesses 208c and secondary recesses 226b extending into the encapsulant 206c from an outer surface 210c of the encapsulant 206c. In the embodiment illustrated in FIG. 2C the primary recesses 208c extend into the encapsulant 206c in an area outside of the horizontal area (e.g., horizontal footprint) of the semiconductor die 202c. The primary recesses 208c are positioned adjacent to lateral surfaces 220c of the semiconductor die 202c. For example, portions of the lateral surfaces 220c of the semiconductor die 202c may define lower boundaries of the primary recesses 208c are. The encapsulant 206c may include multiple primary recesses 208c horizontally positioned around a horizontal perimeter of the semiconductor die 202c. The primary recesses 208c may be configured to define an escape path where vapors may exit the semiconductor device package 200C during one or more of the heating processes. Positioning lower boundaries of the primary recesses 208c at or substantially proximate to the lateral surfaces 220c of the semiconductor die 202c reduces a volume of the mold material of the encapsulant 206c between the primary recesses 208c and an interface 222c between the semiconductor die 202c and the substrate 204c. Thus, moisture trapped in the interface 222c may evaporate and escape through the primary recesses 208c without creating excessive vapor pressures and potentially damaging the semiconductor die 202c or substrate 204c at the interface 222c.

In the embodiment illustrated in FIG. 2C, the secondary recesses 226b extend into portions of the encapsulant 206c vertically overlying and within a horizontal area of the semiconductor die 202c. The encapsulant 206c may include multiple secondary recesses 226b positioned over the semiconductor die 202c. The secondary recesses 226b may be configured to define an escape path where vapors may exit the semiconductor device package 200C during one or more of the heating processes.

In the embodiment illustrated in FIG. 2C, the primary recesses 208c extend to the upper surface 214c of the substrate 204c and the secondary recesses 226b terminate before reaching an upper surface 230b of the semiconductor die 202c. Thus, a bottom boundary 228b of the secondary recesses 226b is positioned a distance 232b from the upper surface 230b of the semiconductor die 202c. The area between the bottom boundary 228b of the secondary recesses 226a and the upper surface 230b of the semiconductor die 202c may be filled with the mold material of the encapsulant 206c. Thus, the mold material of the encapsulant 206c may remain to perform the insulating or other protective functions for any structures of the semiconductor die 202c positioned proximate the secondary recesses 226b. The primary recesses 208c may be positioned over regions of the substrate 204c that are substantially free of conductive structures and electrical components, such that the portions of the upper surface 214c of the substrate 204c exposed by the primary recesses 208c are substantially free of conductive structures and other electrical components.

The primary recesses 208c may be defined by substantially vertical sidewalls 218c of the encapsulant 206c. The sidewalls 218c may be oriented parallel to one another, such that the primary recesses 208c individually exhibit a substantially rectangular cross-sectional shape in a Y plane where an upper boundary of the recesses 208c is defined by the outer surface 210c of the encapsulant 206c. Similarly, the secondary recesses 226b may be defined by substantially vertical sidewalls 234b of the encapsulant 206c. The sidewalls 234b may be oriented parallel to one another, such that the secondary recesses 226b individually exhibit a substantially rectangular cross-sectional shape in a Y plane where an upper boundary of the secondary recesses 226b id defined by the outer surface 210c of the encapsulant 206c. A cross-sectional shape of the primary recesses 208c and the secondary recesses 226b about axes of the respective primary recesses 208c and secondary recesses 226b in an X plane may be any shape, such as circular shapes, oval shapes, rectangular shapes, triangular shapes, among others. As described above, the shapes of the primary recesses 208c, 226b may be selected based on structural features of the substrate 204c and the semiconductor die 202c. The shapes or positions of the recesses 208c, 226b may further be selected based on warpage concerns, such as to reduce a volume of the mold material of the encapsulant 206c in regions most susceptible to warpage.

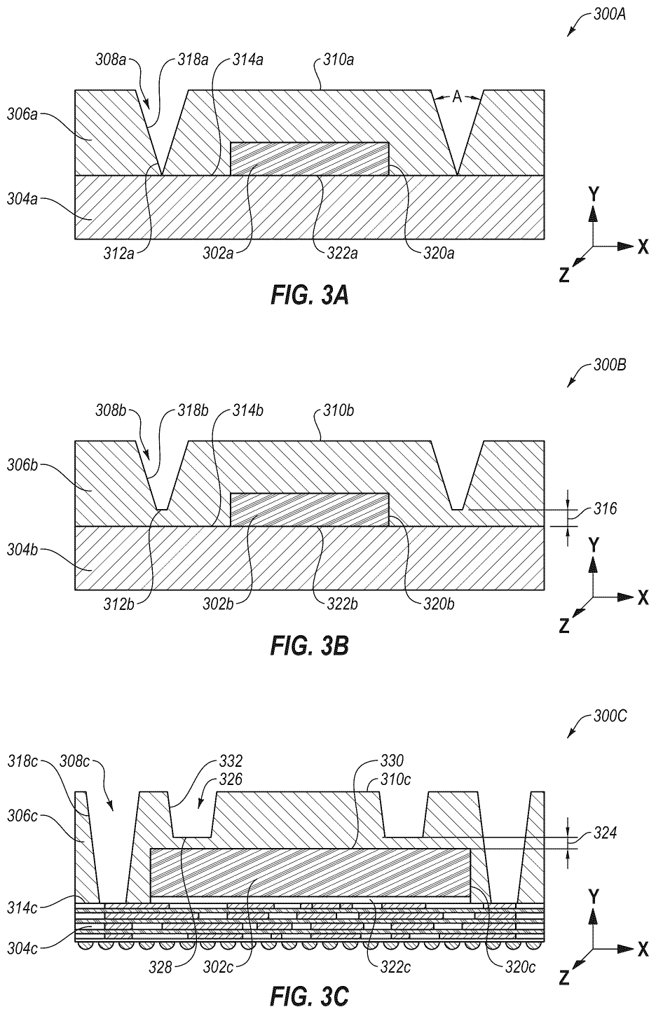

FIG. 3A illustrates a semiconductor device package 300A. The semiconductor device package 300A includes a semiconductor die 302a secured to a substrate 304a (e.g., base structure). In some cases, the semiconductor device package 300A may be a different portion of the semiconductor device package(s) illustrated in one or more of FIGS. 2A-2C. As described above, the substrate 304a may be a package substrate, a redistribution layer (RDL), or an interposer structure. The semiconductor die 302a is electrically coupled to one or more of the conductive structures, such as through solder bumps, wirebonds, and/or other complementary conductive structures (e.g., pins or sockets). The substrate 304a may also include conductive structures that extend beyond a footprint of the semiconductor die 302a, such as traces and/or contact pads for wirebonding.

An encapsulant 306a substantially surrounds the semiconductor die 302a. The encapsulant 306a extends over a portion of an upper surface 314a of the substrate 304a and fully covers the semiconductor die 302a. Recesses 308a extend into the encapsulant 306a from an outer surface 310a (e.g., upper surface) of the encapsulant 306a. In the embodiment illustrated in FIG. 3A the recesses 308a extend into portions of the encapsulant 306a outside of the horizontal area of the semiconductor die 302a. The recesses 308a are positioned vertically adjacent to lateral surfaces 320a of the semiconductor die 302a. The encapsulant 306a may include multiple recesses 308a horizontally positioned around a horizontal perimeter of the semiconductor die 302a. The recesses 308a may be configured to define an escape path where vapors may exit the semiconductor device package 300A during one or more of the heating processes. Positioning the recesses 308a at or substantially proximate the lateral surfaces 320a of the semiconductor die 302a reduces a volume of the mold material of the encapsulant 306a between the recesses 308a and an interface 322a between the semiconductor die 302a and the substrate 304a. Thus, moisture trapped in the interface 322a may evaporate and escape through the recesses 308a without creating excessive vapor pressures and potentially damaging the semiconductor die 302a or substrate 304a at the interface 322a.

The recesses 308a may be at least partially defined by angled (e.g., non-vertically oriented) sidewalls 318a of the encapsulant 306a. The recesses 308a exhibit a substantially triangular vertical cross-sections shape where an upper boundary of the recesses 308a is defined by the outer surface 310a of the encapsulant 306a. In some embodiments, one sidewall 318a extends at an angle and another sidewall 318a defining the same recess 308a may be substantially vertical, similar to the sidewalls 218a, 218b, 218c described in FIGS. 2A-2C. For an individual recess 308a, the sidewalls 318a combine to form an angle A at an apex 312a of the recess 308a. The angle A may be within a range from about 1 degree to about 60 degrees, such as within a range from about 10 degrees to about 45 degrees, or within a range of from about 10 degrees to about 30 degrees. A horizontal (e.g., in an X plane) cross-sectional shape of and individual recess 308a may be any desirable shape, such as a circular shape, an oval shape, a rectangular shape, a triangular shape, or another shape. As described above, the shapes of the recesses 308a may be selected based on structural features of the substrate 304a and the semiconductor die 302a. The shapes or positions of the recesses 308a may further be selected based on warpage concerns, such as to reduce a volume of the mold material of the encapsulant 306a in regions most susceptible to warpage.

In some embodiments, the recesses 308a extend to an upper surface 314a of the substrate 304a as illustrated in FIG. 3A. The recesses 308a extend to the upper surface 314a of the substrate 304a, such that the apex 312a of the recesses 308a is positioned at the upper surface 314a of the substrate 304a. In other embodiments, the recesses 308a expose a portion of the upper surface 314a of the substrate 304a. For example, a recess 308a may be formed such that the adjacent sidewalls 318a of the encapsulant 306a extend to the upper surface 314a of the substrate 304a in different locations and do not meet at an apex 312a exposing the area of the upper surface 314a between the sidewalls 318a.

FIG. 3B illustrates a semiconductor device package 300B. The semiconductor device package 300B includes a semiconductor die 302b secured to a substrate 304b (e.g., base structure). In some cases, the semiconductor device package 300B may be a different portion of the semiconductor device package(s) illustrated in one or more of FIGS. 2A-3A. As described above, the substrate 304b may be a package substrate, a redistribution layer (RDL), or an interposer structure. The semiconductor die 302b is electrically coupled to one or more of the conductive structures, such as through solder bumps, wirebonds, and/or other complementary conductive structures (e.g., pins or sockets). The substrate 304b may also include conductive structures that extend beyond a footprint of the semiconductor die 302b, such as traces and/or contact pads for wirebonding.

An encapsulant 306b substantially surrounds the semiconductor die 302b. The encapsulant 306b extends over a portion of an upper surface 314b of the substrate 304b and fully covers the semiconductor die 302b. Recesses 308b extend into the encapsulant 306b from an outer surface 310b of the encapsulant 306b. In the embodiment illustrated in FIG. 3B the recesses 308b extend into a portion of the encapsulant 306b outside of the horizontal area of the semiconductor die 302b. The recesses 308b are positioned adjacent to lateral surfaces 320b of the semiconductor die 302b. The encapsulant 306b may include multiple recesses 308b horizontally positioned around a horizontal perimeter of the semiconductor die 302b. The recesses 308b may be configured to define an escape path where vapors may exit the semiconductor device package 300B during one or more of the heating processes. Positioning the recesses 308b proximate the lateral surfaces 320b of the semiconductor die 302b reduces a volume of the mold material of the encapsulant 306b between the recesses 308b and an interface 322b between the semiconductor die 302b and the substrate 304b. Thus, moisture trapped in the interface 322b may evaporate and escape through the recesses 308b without creating excessive vapor pressures and potentially damaging the semiconductor die 302b or substrate 304b at the interface 322b.

The recesses 308b may be defined by angled sidewalls 318b of the encapsulant 306b. The recesses 308b exhibit a substantially triangular shape vertical cross-sectional shape where an upper boundary of the recesses 308b is defined by the outer surface 310b of the encapsulant 306b. In some embodiments, one sidewall 318b extends at an angle and another sidewall 318b defining the same recess 308b may be substantially vertical, similar to the sidewalls 218a, 218b, 218c described in FIGS. 2A-2C. The recesses 308b may terminate at a bottom boundary 312b without converging at an apex. In the embodiment illustrated in FIG. 3B, the recesses 308b terminate before reaching the upper surface 314b of the substrate 304b. Thus, the bottom boundary 312b of the recesses 308b is positioned a distance 316 from the upper surface 314b of the substrate 304b. An area between the bottom boundary 312b of the recess 308b and the upper surface 314b of the substrate 304b may be filled with the mold material of the encapsulant 306b. Thus, the mold material of the encapsulant 306b may remain to perform the insulating or other protective functions for any conductive structures of the substrate 304b positioned proximate the recesses 308b.

A horizontal (e.g., in an X plane) cross-sectional shape of and individual recess 308b may be any desirable shape, such as a circular shape, an oval shape, a rectangular shape, a triangular shape, or another shape. As described above, the shapes of the recesses 308b may be selected based on structural features of the substrate 304b and the semiconductor die 302b. The shapes or positions of the recesses 308b may further be selected based on warpage concerns, such as to reduce a volume of the mold material of the encapsulant 306b in regions most susceptible to warpage.

FIG. 3C illustrates a semiconductor device package 300C. The semiconductor device package 300C includes a semiconductor die 302c secured to a substrate 304c (e.g., base structure). In some cases, the semiconductor device package 300C may be a different portion of the semiconductor device package(s) illustrated in one or more of FIGS. 2A-3B. As described above, the substrate 304c may be a package substrate, a redistribution layer (RDL), or an interposer structure. The semiconductor die 302c is electrically coupled to one or more of the conductive structures, such as through solder bumps, wirebonds, and/or other complementary conductive structures (e.g., pins or sockets). The substrate 304c may also include conductive structures that extend beyond a footprint of the semiconductor die 302c, such as traces and/or contact pads for wirebonding.

An encapsulant 306c substantially surrounds the semiconductor die 302c. The encapsulant 306c extends over a portion of an upper surface 314c of the substrate 304c and fully covers the semiconductor die 302c. Primary recesses 308c and secondary recesses 326 extend into the encapsulant 306c from an outer surface 310c of the encapsulant 306c. In the embodiment illustrated in FIG. 3C the primary recesses 308c extend into portions of the encapsulant 306c outside of the horizontal area of the semiconductor die 302c. The primary recesses 308c are positioned adjacent to lateral surfaces 320c of the semiconductor die 302c. The encapsulant 306c may include multiple primary recesses 308c horizontally positioned around a horizontal perimeter of the semiconductor die 302c. The primary recesses 308c may be configured to define an escape path where vapors may exit the semiconductor device package 300C during one or more of the heating processes. Positioning the primary recesses 308c at or substantially proximate to the lateral surfaces 320c of the semiconductor die 302c reduces a volume of the mold material of the encapsulant 306c between the primary recesses 308c and an interface 322c between the semiconductor die 302c and the substrate 304c. Thus, moisture trapped in the interface 322c may evaporate and escape through the primary recesses 308c without creating excessive vapor pressures and potentially damaging the semiconductor die 302c or substrate 304c at the interface 322c.

In the embodiment illustrated in FIG. 3C, the secondary recesses 326 extend into a portion of the encapsulant 306c vertically above and within a horizontal area of the semiconductor die 302c. The encapsulant 306c may include multiple secondary recesses 326 therein. The secondary recesses 326 may be configured to define an escape path where vapors may exit the semiconductor device package 300C during one or more of the heating processes.

The primary recesses 308c may be defined by angled sidewalls 318c in the encapsulant 306c. The primary recesses 308c exhibit a substantially triangular vertical cross-sectional shape where an upper boundary of the primary recesses 308c is defined by the outer surface 310c of the encapsulant 306c. In some embodiments, one sidewall 318c extends at an angle and another sidewall 318c defining the same recess 308c may be substantially vertical, similar to the sidewalls 218a, 218b, 218c described in FIGS. 2A-2C. A horizontal (e.g., in an X plane) cross-sectional shape of an individual primary recess 308c may be any desirable shape, such as a circular shape, an oval shape, a rectangular shape, a triangular shape, or another shape. As described above, the shapes of the primary recesses 308c may be selected based on structural features of the substrate 304c and the semiconductor die 302c. The shapes or positions of the recesses 308c may further be selected based on warpage concerns, such as to reduce a volume of the mold material of the encapsulant 306c in regions most susceptible to warpage.

In some embodiments, the primary recesses 308c extend to an upper surface 314c of the substrate 304c as illustrated in FIG. 3C. In some embodiments, the primary recesses 308c extend to the upper surface 314c of the substrate 304c, such that an apex of the primary recesses 308c is positioned at the upper surface 314c of the substrate 304c. In other embodiments, as illustrated in FIG. 3C the primary recesses 308c may expose a portion of the upper surface 314c of the substrate 304c, such that a bottom boundary of the individual primary recesses 308c is formed by the upper surface 314c of the substrate 304c. For example, a primary recess 308c may be defined such that the adjacent sidewalls 318c defining the primary recess 308c do not meet at an apex such that the area of the upper surface 314c is exposed between the sidewalls 318c.

The secondary recesses 326 may also be defined by angled sidewalls 332 in the encapsulant 306c. The secondary recesses 326 also exhibit a substantially triangular vertical cross-sectional shape where an upper boundary of the primary recesses 308c is defined by the outer surface 310c of the encapsulant 306c. In some embodiments, one sidewall 318c extends at an angle and another sidewall 318c defining the same recess 308c may be substantially vertical, similar to the sidewalls 234a, 234b described in FIGS. 2B and 2C. The sidewalls 332 may each terminate at a bottom boundary 328 without converging at an apex. In the embodiment illustrated in FIG. 3C, the secondary recesses 326 terminate before reaching the upper surface 330 of the semiconductor die 302c. Thus, the bottom boundary 328 of the secondary recess 326 is positioned a second distance 324 from the upper surface 330 of the semiconductor die 302c. The area between the bottom boundary 328 of the secondary recess 326 and the upper surface 330 of the semiconductor die 302c may be filled with the mold material of the encapsulant 306c. Thus, the mold material of the encapsulant 306c may remain to perform the insulating or other protective functions for the semiconductor die 302c.

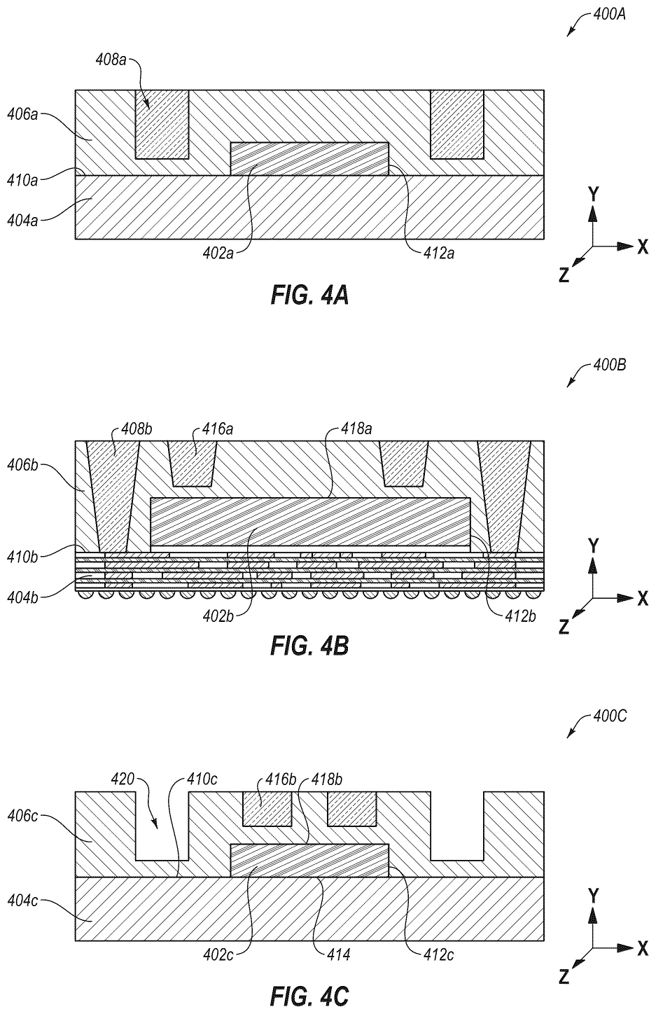

In some embodiments, one or more of the recesses (e.g., recesses 208a, 208b, 208c, 226a, 226b, 308a, 308b, 308c, 326) may be filled with another material. For example, the recesses may be filled with a material having a different CTE than the encapsulant that is configured to control warpage of the associated semiconductor device package. FIGS. 4A through 4C illustrate schematic cross-sectional views of different embodiments of semiconductor device packages including one or more filled in recesses.

FIG. 4A illustrates a semiconductor device package 400A. The semiconductor device package 400A includes a semiconductor die 402a over a substrate 404a (e.g., base structure) and is encapsulated by an encapsulant 406a. A fill material 408a is positioned in one or more recesses of the encapsulant 406a, such that the fill material 408a substantially fills the one or more recesses. The fill material 408a may be positioned outside of a horizontal area of the semiconductor die 402a. For example, the fill material 408a may be positional horizontally outward of lateral surfaces 412a of the semiconductor die 402a. In some embodiments, the fill material 408a terminates at the upper surface 410a of the substrate 404a, such that the fill material 408a is in direct contact with the upper surface 410a of the substrate 404a. In other embodiments, as illustrated in FIG. 4A, the fill material 408a terminates a distance above the upper surface 410a of the substrate 404a, such that mold material of the encapsulant 406a is positioned between the fill material 408a and the upper surface 410a of the substrate 404a.

In some embodiments, the fill material 408a is configured to control warpage in the semiconductor device package 400A. For example, the fill material 408a may have a CTE greater than the surrounding mold material of the encapsulant 406a to induce warpage in the regions corresponding to the fill material 408a. In another example, the fill material 408a may have a CTE less than the surrounding mold material of the encapsulant 406a to inhibit warpage in the regions corresponding to the fill material 408a.

In some embodiments, the fill material 408a is a second mold material (e.g., epoxy molding compound) formed in a second molding process. In other embodiments, the fill material 408a is a thermosetting polymer material injected or flowed into the associated recesses and subsequently cured through a heating process.

FIG. 4B illustrates a semiconductor device package 400B. The semiconductor device package 400B includes a semiconductor die 402b over a substrate 404b (e.g., base structure) and is encapsulated by an encapsulant 406b. A primary fill material 408b is positioned in one or more recesses of the encapsulant 406b, such that the primary fill material 408b substantially fills the one or more recesses. The primary fill material 408b may be positioned outside of a horizontal area of the semiconductor die 402b. For example, the fill material 408b may be positional horizontally outward of adjacent lateral surfaces 412b of the semiconductor die 402b. In some embodiments, the primary fill material 408b terminates at the upper surface 410b of the substrate 404b, as illustrated in FIG. 4B, such that the primary fill material 408b is in direct contact with the upper surface 410b of the substrate 404b. In other embodiments, the primary fill material 408b terminates a distance above the upper surface 410b of the substrate 404b, such that mold material of the encapsulant 406b is positioned between the primary fill material 408b and the upper surface 410b of the substrate 404b.

As illustrated in FIG. 4B, a secondary fill material 416a is positioned in secondary recesses (e.g., secondary recesses 226a (FIG. 2A), 226b (FIG. 2B), 326 (FIG. 3C)) vertically overlying and within a horizontal area of the semiconductor die 402b. The secondary fill material 416a may substantially fill the secondary recesses. The secondary fill material 416a may be positioned vertically over and within the horizontal area of the semiconductor die 402b. In some embodiments, the secondary fill material 416a terminates at an upper surface 418a of the semiconductor die 402b, such that the secondary fill material 416a is in direct contact with the upper surface 418a of the semiconductor die 402b. In other embodiments, as illustrated in FIG. 4B, the secondary fill material 416a terminates a distance above the upper surface 418a of the semiconductor die 402b, such that the mold material of the encapsulant 406b is positioned between the secondary fill material 416a and the upper surface 418a of the semiconductor die 402b.

In some embodiments, at least one of the primary fill material 408b and the secondary fill material 416a is configured to control warpage in the semiconductor device package 400B. For example, at least one of the primary fill material 408b and the secondary fill material 416a may be a material having a CTE greater than the surrounding mold material of the encapsulant 406b to induce warpage in the regions corresponding to the primary fill material 408b or the secondary fill material 416a. In another example, at least one of the primary fill material 408b and the secondary fill material 416a may be a material having a CTE less than the surrounding mold material of the encapsulant 406b to inhibit warpage in the regions corresponding to the primary fill material 408b or the secondary fill material 416a.

In some embodiments, different fill materials are used at different locations. For example, the primary fill material 408b may be a material configured to inhibit warpage (e.g., having a CTE less than the mold material of the encapsulant 406b) and the secondary fill material 416a may be a material configured to induce warpage (e.g., having a CTE that is greater than the mold material of the encapsulant 406b) to achieve the desired warpage control. In another example, the primary fill material 408b may be a material configured to induce warpage (e.g., having a CTE greater than the mold material of the encapsulant 406b) and the secondary fill material 416a may be a material configured to inhibit warpage (e.g., having a CTE that is less than the mold material of the encapsulant 406b) to achieve the desired warpage control.

In some embodiments, the primary fill material 408b and/or the secondary fill material 416a is a mold material (e.g., epoxy molding compound) formed in a second molding process. In other embodiments, the primary fill material 408b and/or the secondary fill material 416a is a thermosetting polymer material injected or flowed into the associated recesses and subsequently cured through a heating process.

FIG. 4C illustrates a semiconductor device package 400C. The semiconductor device package 400C includes a semiconductor die 402c over a substrate 404c (e.g., base structure) and is encapsulated by an encapsulant 406c. The encapsulant 406c includes one or more recesses 420 therein. The recesses 420 may be positioned outside of a horizontal area of the semiconductor die 402c. For example, the fill material 408b may be positional horizontally outward of lateral surfaces 412c of the semiconductor die 402c. In some embodiments, the recesses 420 terminates at the upper surface 410c of the substrate 404c, such that a portion of the upper surface 410c of the substrate 404c is exposed through the recesses 420. In other embodiments, as illustrated in FIG. 4C, the recess 420 terminates a distance above the upper surface 410c of the substrate 404c, such that mold material of the encapsulant 406c is positioned between the recesses 420 and the upper surface 410c of the substrate 404c. The recesses 420 may be configured to define an escape path where vapors may exit the semiconductor device package 400C during one or more of the heating processes. Positioning the recesses 420 proximate the lateral surfaces 412c of the semiconductor die 402c reduces a volume of the mold material of the encapsulant 406c between the recesses 420 and an interface 414 between the semiconductor die 402c and the substrate 404c. Thus, moisture trapped in the interface 414 may evaporate and escape through the recesses 420 without creating excessive vapor pressures and potentially damaging the semiconductor die 402c or substrate 404c at the interface 414.

As illustrated in FIG. 4C, a secondary fill material 416b is positioned in secondary recesses (e.g., secondary recesses 226a, 226b, 326) over the semiconductor die 402c. The secondary fill material 416b may substantially fill the secondary recesses. In some embodiments, the secondary fill material 416b may terminate at an upper surface 418b of the semiconductor die 402c, such that the secondary fill material 416b is in direct contact with the upper surface 418b of the semiconductor die 402c. In other embodiments, as illustrated in FIG. 4C, the secondary fill material 416b terminates a distance above the upper surface 418b of the semiconductor die 402c, such that the mold material of the encapsulant 406c is positioned between the secondary fill material 416b and the upper surface 418b of the semiconductor die 402c.

In some embodiments, the secondary fill material 416b is configured to control warpage in the semiconductor device package 400C. For example, the secondary fill material 416b may be a material having a CTE greater than the surrounding mold material of the encapsulant 406c to induce warpage in the regions corresponding to the secondary fill material 416b. In another example, the secondary fill material 416b may be a material having a CTE less than the surrounding mold material of the encapsulant 406c to inhibit warpage in the regions corresponding to the secondary fill material 416b.

In some embodiments, the secondary fill material 416b is a mold material (e.g., epoxy molding compound) formed in a second molding process. In other embodiments, the secondary fill material 416b is a thermosetting polymer material injected or flowed into the associated recesses and subsequently cured through a heating process.

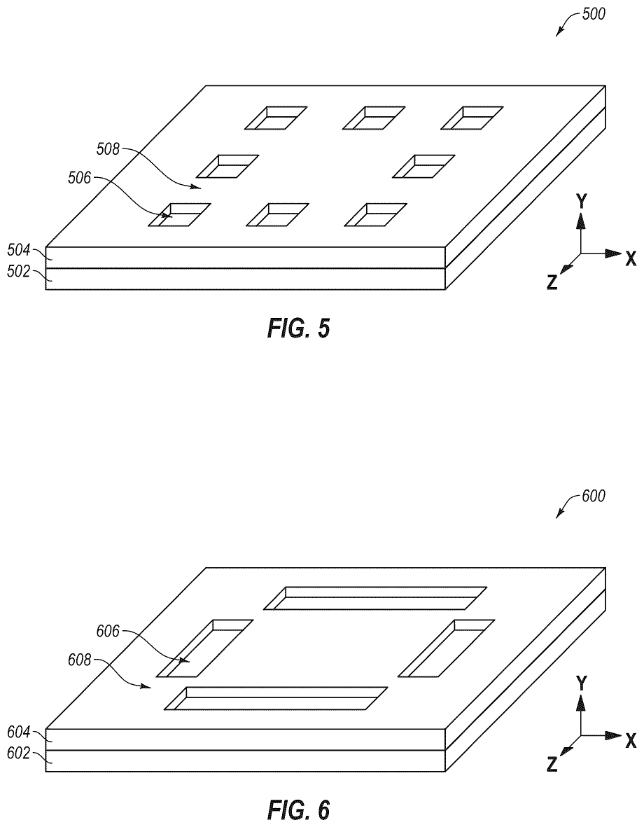

FIG. 5 and FIG. 6 illustrate simplified, perspective views of different embodiments of semiconductor device packages having different patterns of recesses defined in the surface of the encapsulant. FIG. 5 illustrates a simplified, perspective view of a semiconductor device package 500 including multiple recesses 506 having a substantially square horizontal cross-sectional area. The recesses 506 extend into an encapsulant 504 positioned over a substrate 502. The recesses 506 are separated by full thickness regions of the encapsulant 504, such that an outer surface 508 of the encapsulant 504 extends between the recesses 506. The recesses 506 may form square shaped openings in the outer surface 508 of the encapsulant 504. In other embodiments, the recesses 506 form openings in the outer surface 508 of the encapsulant 504 having one or more other horizontal cross-sectional shapes, such as circular shapes, triangular shapes, and/or rectangular shapes. The recesses 506 may constitute at least about 5% of the horizontal area of the encapsulant 504, such as within range from about 5% of the total horizontal area of the encapsulant 504 to about 70% of the total horizontal area of the encapsulant 504, or from about 40% of the total horizontal area of the outer surface 508 to about 60% of the total horizontal area of the encapsulant 504.

As described above, the recesses 506 may be horizontally positioned around a horizontal perimeter of a semiconductor die, such as semiconductor die 202a, 202b, 202c, 302a, 302b, 302c, 402a, 402b, 402c, illustrated in FIGS. 2A-4C, respectively. In other embodiments, the recesses 506 may be positioned to at least partially horizontally overlap the semiconductor die. As described above, one or more of the recesses 506 may be filled with a fill material, such as another molding compound having a CTE that is different from the material of the encapsulant 504.

In the embodiment illustrated in FIG. 5, the multiple recesses 506 are arranged in a substantially uniform or symmetrical distribution. In other embodiments, the multiple recesses 506 are arranged in non-uniform or asymmetrical distributions. For example, the spacing between the multiple recesses 506 created by the full thickness regions of the encapsulant 504 may be different between different recesses 506. Some of the multiple recesses 506 may have different shapes (e.g., horizontal cross-sectional shapes) and/or sizes (e.g., horizontal areas and/or major cross-sectional dimensions) from other recesses 506 in the encapsulant 504. For example, recesses 506 positioned over a semiconductor die (e.g., that horizontally overlap the semiconductor die) may have different properties (e.g., shapes, sizes, arrangements) than the recesses 506 arranged outside of the horizontal perimeter of the semiconductor die.

FIG. 6 illustrates simplified, perspective view of a semiconductor device package 600 including multiple recesses 606 having a substantially rectangular horizontal cross-sectional area. The recesses 606 extend into an encapsulant 604 positioned over a substrate 602. The recesses 606 are separated by full thickness regions of the encapsulant 604, such that an outer surface 608 of the encapsulant 604 extends between the recesses 606. The recesses 606 may form elongated openings in the outer surface 608 of the encapsulant 604, such as rectangular shaped openings or oval shaped openings. In other embodiments, the recesses 606 form openings in the outer surface 608 of the encapsulant 604 having other abstract shapes, such as “C” shaped openings, “E” shaped openings, among others. As described above, the shapes of the openings may be determined based on conductive structures of the substrate 602 or the semiconductor die (not shown). The openings in the outer surface 608 defined by the recesses 606 may constitute at least about 5% of the total horizontal area of the encapsulant 604, such as in range from about 5% of the total horizontal area of the encapsulant 604 to about 70% of the total horizontal area of the encapsulant 604, or from about 40% of the total horizontal area of the encapsulant 604 to about 60% of the total horizontal area of the encapsulant 604. As described above, one or more of the recesses 606 may be filled with a fill material, such as another molding compound having a CTE that is different from the material of the encapsulant 604.

As described above, the recesses 606 may be horizontally positioned around a horizontal perimeter of a semiconductor die, such as semiconductor die 202a, 202b, 202c, 302a, 302b, 302c, 402a, 402b, 402c, illustrated in FIGS. 2A-4C, respectively. In other embodiments, the recesses 606 may be positioned to at least partially horizontally overlap the semiconductor die.

In the embodiment illustrated in FIG. 6, the multiple recesses 506 are arranged in a substantially symmetrical distribution. In other embodiments, the multiple recesses 506 are arranged in asymmetrical distributions. For example, the spacing between the multiple recesses 606 created by the full thickness regions of the encapsulant 604 may be different between different recesses 606. Some of the multiple recesses 606 may have different shapes (e.g., horizontal cross-sectional shapes) and/or sizes (e.g., horizontal areas and/or major cross-sectional dimensions) from other recesses 606 in the encapsulant 604. For example, recesses 606 positioned over a semiconductor die (e.g., that horizontally overlap the semiconductor die) may have different properties (e.g., shapes, sizes, arrangements) than the recesses 606 arranged outside of the horizontal perimeter of the semiconductor die.

In the embodiment illustrated in FIG. 6, the recesses 606 are arranged in substantially parallel arrangements with outer edges of the encapsulant 604 and/or semiconductor die. In other embodiments, one or more of the recesses 606 are arranged to extend horizontally at an angle relative to the outer edges of one or more of the encapsulant 604 and the semiconductor die, such as diagonally across the upper surface of the semiconductor device package 600. In some embodiments, the semiconductor device package 600 or 500 includes a combination of both recesses 506 and elongated recesses 606 extending into the associated encapsulant 504, 604.

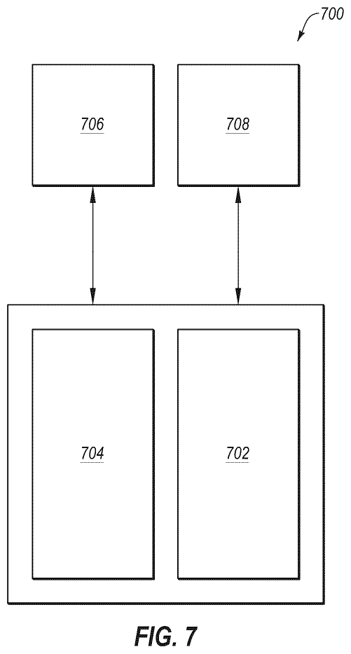

Microelectronic devices (e.g., the semiconductor device packages 100, 400 including the stacked structures of the disclosure) may be included in embodiments of electronic systems of the disclosure. For example, FIG. 7 is a block diagram of an electronic system 700, in accordance with embodiments of the disclosure. The electronic system 700 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 700 includes at least one memory device 702. The memory device 702 may include, for example, an embodiment of a semiconductor device package previously described herein (e.g., the semiconductor device package 100, 200A, 200B, 200C, 300A, 300B, 300C, 400A, 400B, 400C, 500, or 600 previously described with reference to FIGS. 1 through 6).

The electronic system 700 may further include at least one electronic signal processor device 704 (often referred to as a “microprocessor”). The electronic signal processor device 704 may, optionally, include an embodiment of one or more of a microelectronic device and a microelectronic device structure previously described herein. The electronic system 700 may further include one or more input devices 706 for inputting information into the electronic system 700 by a user, such as, for example, a mouse or other pointing device, a keyboard, a touchpad, a button, or a control panel. The electronic system 700 may further include one or more output devices 708 for outputting information (e.g., visual or audio output) to a user such as, for example, a monitor, a display, a printer, an audio output jack, a speaker, etc. In some embodiments, the input device 706 and the output device 708 may comprise a single touchscreen device that can be used both to input information to the electronic system 700 and to output visual information to a user. The input device 706 and the output device 708 may communicate electrically with one or more of the memory device 702 and the electronic signal processor device 704.

Thus, embodiments of the disclosure include a microelectronic device. The device includes a semiconductor die operatively coupled to a base structure. The device further includes an encapsulant substantially surrounding the semiconductor die. The device also includes one or more recesses vertically extending from an upper surface of the encapsulant to one or more locations at or proximate to an upper surface of the base structure.

Another embodiment of the disclosure includes an electronic system. The system includes an input device, an output device, a processor device operably coupled to the input device and the output device, and a memory device operably coupled to the processor device. The memory device includes a semiconductor die coupled to a base structure. The memory device further includes an encapsulant substantially surrounding the semiconductor die. The memory device also includes a recess defined in the encapsulant.

Other embodiments of the disclosure include a method of forming a microelectronic device. The method includes positioning a semiconductor die over a substrate. The method further includes encapsulating the semiconductor die in a first mold material. The method also includes forming one or more recesses in the first mold material. The method further includes heating the microelectronic device after forming the one or more recesses.

Embodiments of the disclosure provide microelectronic devices or semiconductor device packages configured to provide escape paths from the evacuation of moisture from within the respective devices or packages. Moisture trapped within the devices may expand as a vapor when the devices are heated during different forming and curing processes. Facilitating the evacuation of the fluids and vapors may reduce vapor pressures within the respective devices and packages, which may in turn reduce device failures caused by vapor pressures, such as delaminations, shorts, or open connections.

Embodiments of the disclosure also provide options for reducing a volume of materials having different CTEs from the other materials in the respective packages. Reducing the volume of the materials having different CTEs may result in a reduction in warpage experienced by the respective devices and packages. Other embodiments may further control warpage of the associated devices or packages by providing additional materials having CTEs selected to inhibit or induce warpage of the associated device or package. Controlling warpage may facilitate matching a warpage profile of adjacent packages or devices to which the associated device or package will be coupled. Matching a warpage profile may facilitate a better connection between the two devices or packages and improve a yield of the devices.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device comprising:
a semiconductor die operatively coupled to a base structure; and
an encapsulant substantially surrounding the semiconductor die; and
one or more recesses vertically extending from an upper surface of the encapsulant to one or more locations at or proximate to an upper surface of the base structure.

2. The microelectronic device of claim 1, wherein a lower boundary of the one or more recesses is vertically positioned at an interface between the semiconductor die and the base structure.

3. The microelectronic device of claim 1, wherein the one or more recesses are positioned outside of a horizontal area of the semiconductor die.

4. The microelectronic device of claim 1, wherein a lower boundary of the one or more recesses is vertically positioned between an upper surface of the semiconductor die and the upper surface of the base structure.

5. The microelectronic device of claim 1, further comprising one or more additional recesses vertically extending through a portion of the encapsulant within a horizontal area of the semiconductor die, the one or more additional recesses vertically extending from the upper surface of the encapsulant to one or more additional locations at or proximate to an upper surface of the semiconductor die.

6. The microelectronic device of claim 1, further comprising a fill material substantially filling at least one of the one or more recesses.

7. The microelectronic device of claim 6, wherein the fill material comprises a material having a coefficient of thermal expansion (CTE) less than a CTE of the encapsulant.

8. The microelectronic device of claim 1, wherein one or more recesses individually exhibit a rectangular vertical cross-sectional shape or a triangular vertical cross-sectional shape.

9. The microelectronic device of claim 1, wherein the one or more recesses are horizontally positioned outside of horizontal areas of conductive structures of the base structure and the semiconductor die.

10. An electronic system comprising:
an input device;
an output device;
a processor device operably coupled to the input device and the output device; and
a memory device operably coupled to the processor device and comprising:
a semiconductor die coupled to a base structure;
an encapsulant substantially surrounding the semiconductor die; and
a recess defined in the encapsulant.

11. The electronic system of claim 10, wherein the recess is horizontally positioned outside of a horizontal area of the semiconductor die.

12. The electronic system of claim 11, wherein the recess is partially defined by two substantially vertical sidewalls of the encapsulant oriented parallel to one another.

13. The electronic system of claim 11, wherein the recess is partially defined by two sidewalls of the encapsulant that converge with one another at an angle.

14. The electronic system of claim 13, wherein the angle is within a range from about 1 degree to about 60 degrees.

15. The electronic system of claim 10, wherein the recess vertically extends to an upper surface of the base structure.

16. A method of forming a microelectronic device, the method comprising:
positioning a semiconductor die over a substrate;
encapsulating the semiconductor die in a first mold material;
forming one or more recesses in the first mold material; and
heating the microelectronic device after forming the one or more recesses.

17. The method of claim 16, further comprising filling at least one of the one or more recesses with a second mold material having a second coefficient of thermal expansion (CTE) different than a first CTE of the first mold material.

18. The method of claim 17, wherein filling the at least one of the one or more recesses with the second mold material comprises filling a recess positioned vertically over and within a horizontal area of the semiconductor die with the second mold material.

19. The method of claim 16, wherein forming one or more recesses in the first mold material comprises forming at least one of the one or more recesses to be at least partially horizontally positioned outside of a horizontal area of the semiconductor die.

20. The method of claim 16, wherein forming the one or more recesses in the first mold material comprises forming the one or more recesses using complementary protrusions extending from a mold.
